(19) United States
(12) Patent Application Publication
(10) Pub. No.: US 2026/0185211 A1
(43) Pub. Date: Jul. 2, 2026

(54) THIN FILM FORMING DEVICE

(71) Applicant: SAMSUNG DISPLAY CO., LTD., YONGIN-SI (KR)

(72) Inventors: Sam Tae JEONG, Yongin-si (KR); Do Keun SONG, Yongin-si (KR); Su Kyoung YANG, Yongin-si (KR)

(21) Appl. No.: 19/377,285

(22) Filed: Nov. 3, 2025

(30) Foreign Application Priority Data
Dec. 27, 2024 (KR) 10-2024-0198759

(51) Int. Cl. C23C 14/46; C23C 14/34; H01J 37/34

(52) U.S. Cl. CPC C23C 14/46; C23C 14/3407; H01J 37/3417; H01J 37/3435; H01J 37/345; H01J 2237/332

(57) ABSTRACT

A thin film forming device including a thin film particle generator including a target, where the target is configured to emit thin film particles, a particle beam generator configured to generate positive ions, and a shield disposed between the thin film particle generator and the particle beam generator. The shield includes a first shield wing, a shield window, and a second shield wing, the shield window includes an opening formed between the first shield wing and the second shield wing, and the shield window is configured to receive the thin film particles. The particle beam generator is directed toward at least one of the first shield wing or the second shield wing.

### CROSS-REFERENCE TO RELATED APPLICATION AND CLAIM OF PRIORITY

This non-provisional patent application claims priority under 35 U.S.C. § 119 to Korean Patent Application No. 10-2024-0198759 filed on Dec. 27, 2024 in the Korean Intellectual Property Office (KIPO), the entire disclosure of which is incorporated by reference herein in its entireties.

### TECHNICAL FIELD

Embodiments of the present disclosure relate to a thin film forming device.

### BACKGROUND

In a process of physically depositing electrodes onto a display of an electronic device, crystallization of the deposited electrodes may be required. However, increasing the temperature of the display to achieve the crystallization of the deposited electrodes may degrade the quality of the display. Additionally, applying charged particles to facilitate the crystallization of the display may also reduce the quality of the display.

### SUMMARY

Embodiments of the present disclosure provide a thin film forming device including thin film particle generator including a target, where the target is configured to emit thin film particles; a particle beam generator configured to generate positive ions; and a shield disposed between the thin film particle generator and the particle beam generator, where the shield including a first shield wing, a shield window, and a second shield wing, the shield window includes an opening formed between the first shield wing and the second shield wing, and the shield window is configured to receive the thin film particles, and where the particle beam generator is directed toward at least one of the first shield wing or the second shield wing.

In some embodiments, the particle beam generator is configured to emit the positive ions at an angle toward at least one of the first shield wing or the second shield wing.

In some embodiments, the particle beam generator may include a particle beam chamber including a particle beam chamber body and an ion slit formed in the particle beam chamber body; and an ion extraction electrode including an ion extraction electrode body and an ion extraction electrode slit formed in the ion extraction electrode body, where the ion extraction electrode body is opposite from the particle beam chamber body.

In some embodiments, the ion extraction electrode slit and the ion slit may be opposite from each other and be parallel to the target.

In some embodiments, an electric potential of the ion extraction electrode may be lower than an electric potential of the particle beam chamber.

In some embodiments, the particle beam generator is configured to generate neutral particles by combining the positive ions and electrons, and the positive ions incident on the first shield wing or the second shield wing are reflected.

In some embodiments, the thin film particle generator may include a mount rotatably coupled to the target; a magnet disposed in a hollow portion formed in the target and connected to the mount; a casing including a casing body surrounding the target and a casing window formed in the casing body; and a plasma housing including a plasma housing body surrounding the casing and a plasma housing window formed in the plasma housing body.

In some embodiments, the casing window and the plasma housing window are aligned with the magnet.

In some embodiments, an inner surface of the plasma housing body and an outer surface of the casing body may face each other and be spaced apart from each other to form a plasma space.

In some embodiments, the thin film particle generator may include a first thin film particle generator and a second thin film particle generator spaced apart from each other. The first shield wing may be disposed below the first thin film particle generator, and the second shield wing may be disposed below the second thin film particle generator.

In some embodiments, the thin film forming device may further include a plasma chamber configured to generate plasma, where the plasma chamber surrounds the first thin film particle generator and the second thin film particle generator.

In some embodiments, a top layer of the first shield wing facing is opposite from the thin film particle generator, and a bottom layer of the first shield wing is opposite from the particle beam generator and the top layer and the bottom layer are spaced apart from each other.

In some embodiments, the top layer includes a positive electric potential, and the bottom layer includes a negative electric potential.

Embodiments of the present disclosure provide a thin film forming device including thin film particle generator including a target, where the target is configured to emit thin film particles; a particle beam generator configured to generate positive ions; and a shield disposed between the thin film particle generator and the particle beam generator, the shield including a first shield wing, a shield window, and a second shield wing; the shield window includes an opening formed between the first shield wing and the second shield wing. and the shield window is configured to receive the thin film particles, where the particle beam generator including a particle beam chamber including a particle beam chamber body; and an ion extraction electrode including an ion extraction electrode body opposite from a side surface of the particle beam chamber body, the particle beam chamber being disposed between the shield and the ion extraction electrode.

In some embodiments, the particle beam chamber may include an ion slit formed in the particle beam chamber body. The ion extraction electrode may include an ion extraction electrode slit formed in the ion extraction electrode body, the ion extraction electrode slit is opposite from the ion slit.

In some embodiments, an electric potential of the ion extraction electrode may be lower than an electric potential of the particle beam chamber. The particle beam generator may include an electron extraction electrode including an electron extraction electrode body opposite and spaced apart from a first side of the particle beam chamber and an electron extraction electrode slit formed in the electron extraction electrode body; and an electron guide segment configured to generate a magnetic field. The particle beam chamber may include an electron slit formed in the first side of the particle beam chamber body.

In some embodiments, the electron extraction electrode slit and the electron slit may be aligned, and an electric potential of the electron extraction electrode may be higher than the electric potential of the particle beam chamber.

In some embodiments, the magnetic field formed by the electron guide segment may be located on an opposite side of the particle beam chamber with respect to the electron extraction electrode.

Embodiments of the present disclosure provide a thin film forming device including thin film particle generator including a target, the target is configured to emit thin film particles; a particle beam generator configured to generate negative ions; a shield disposed between the thin film particle generator and the particle beam generator; and a laser configured to emit a laser beam to the negative ions to generate neutral particles, the shield including a first shield wing, a shield window, and a second shield wing arranged; and a shield window includes an opening formed between the first shield wing and the second shield wing, and the shield window is configured to receive the thin film particles.

In some embodiments, the particle beam generator may include a particle beam chamber including a particle beam chamber body and an ion slit formed in the particle beam chamber body; and an ion extraction electrode including an ion extraction electrode body opposite and spaced apart from a side of the particle beam chamber body and an ion extraction electrode slit formed in the ion extraction electrode body. The particle beam chamber may be disposed between the ion extraction electrode and the shield.

### BRIEF DESCRIPTION OF THE DRAWINGS

FIG. 1 illustrates a display is loaded on a carrier according to an embodiment of the present disclosure.

FIG. 2 illustrates a cross section of the display illustrated in FIG. 1 taken along the cross-sectional line A1-A2 according to an embodiment of the present disclosure.

FIG. 3 illustrates a thin film particle providing module according to an embodiment of the present disclosure.

FIG. 4 illustrates a cross section of the thin film particle providing module illustrated in FIG. 3.

FIG. 5 illustrates a case and a plasma housing are coupled to a target illustrated in FIG. 4 according to an embodiment of the present disclosure.

FIG. 6 illustrates a shield according to an embodiment of the present disclosure.

FIG. 7 illustrates a cross section of the shield illustrated in FIG. 6 according to an embodiment of the present disclosure.

FIG. 8 is a cross-sectional view illustrating that a thin film forming device is disposed on the display illustrated in FIG. 1 according to an embodiment of the present disclosure.

FIG. 9 illustrates a plasma chamber including the thin film particle providing module illustrated in FIG. 8 according to an embodiment of the present disclosure.

FIG. 10 illustrates a thin film particle generator including a plasma housing according to an embodiment of the present disclosure.

FIG. 11 illustrates a particle beam generator according to an embodiment of the present disclosure.

FIG. 12 illustrates a cross section of the particle beam generator illustrated in FIG. 11 taken along cross-sectional line B1-B2.

FIG. 13 illustrates an electron extraction electrode and the particle beam generator illustrated in FIG. 11 according to an embodiment of the present disclosure.

FIG. 14 illustrates a cross section of the particle beam generator illustrated in FIG. 13 taken along cross-sectional line C1-C2.

FIG. 15 illustrates the particle beam generator and the thin film forming device according to an embodiment of the present disclosure.

FIG. 16 illustrates that the particle beam generator and the thin film forming device according to an embodiment of the present disclosure.

FIG. 17 illustrates a power source connected to the shield according to an embodiment of the present disclosure.

### DETAILED DESCRIPTION OF THE EMBODIMENTS

As described herein, an XYZ coordinate system may be used in the drawings as a cartesian coordinate system. For example, a positive Z-axis direction may indicate an upward direction, and a negative Z-axis direction may indicate a downward direction. For example, a positive X-axis direction may indicate a rearward direction, and a negative X-axis direction may indicate a forward direction. For example, a positive Y-axis direction may indicate a right direction, and a negative Y-axis direction may indicate a left direction.

Hereinafter, preferred embodiments of the present invention are described in detail with reference to the accompanying drawings. It should be noted that in the following description, the parts necessary to understand the operation according to the present invention are described, and the description of other parts may be omitted so as not to obscure the gist of the present invention. Furthermore, the present invention is not limited to the embodiments described herein, and may be embodied in other forms. However, the embodiments described herein are provided to explain the technical idea of the present invention in detail to a person having ordinary skill in the art to which the present invention pertains so that the technical idea can be easily implemented.

Throughout the specification, when a part is “connected” to another part, this includes not only “directly connected” but also “indirectly connected” with another element interposed therebetween. For example, a first layer connected to a second layer may represent the first layer directly connected to the second layer or the first layer is connected to the second layer having an intermediate layer disposed therebetween. The terminology used herein is for the purpose of describing particular embodiments and is not intended to limit the invention.

Throughout the specification, when a part “comprises” a certain component, other components may be further included instead of excluding other components unless otherwise specified. “At least one of X, Y, or Z” and “at least one selected from the group consisting of X, Y or Z” may be interpreted as one X, one Y, one Z, or any combination of two or more of X, Y or Z (e.g., XYZ, XYY, YZ, ZZ). As used herein, “and/or” includes any combination of one or more of those elements.

As used herein, although terms such as first, second, etc. may be used to describe various components, these components are not limited to these terms. These terms are used to distinguish one component from another. Thus, a first component may refer to a second component without departing from what is disclosed herein.

Spatially relative terms such as “below”, “above”, and the like may be used for purposes of explanation, thereby describing the relationship of one element or feature to another element (s) or feature(s), as illustrated in the figures. Spatially relative terms are intended to include different directions in use, operation, and/or manufacture in addition to the directions depicted in the figures. For example, if the device shown in the figure is inverted, the elements depicted as being “below” other elements or features are positioned in the direction “above” the other elements or features. Thus, in one embodiment, the term “below” may include both directions. Furthermore, the device may be directed in another direction (e.g., rotated 90 degrees or in another direction), and thus the spatially relative terms used herein are interpreted accordingly.

Various embodiments are described with reference to the figures schematizing ideal embodiments. It will thus be envisaged that the shapes may vary, for example, based on tolerances and/or manufacturing techniques. Accordingly, the embodiments disclosed herein are not to be construed as limited to the particular shapes shown, but are to be construed as including, for example, changes in shapes that occur as a result of fabrication. As such, the shapes shown in the figures may not show actual shapes of regions of the apparatus, and the present embodiments are not limited thereto.

Embodiments of the present disclosure provides a thin film forming device (or apparatus) including a thin film particle generator which includes a target, where the target is configured to emit thin film particles. The device further includes a shield including a first shield wing, a second shield wing, and a shield window disposed between the first shield wing and the second shield wing. The shield wings are configured to block negatively charged impurities while the shield window is configured to receive target particles. In one aspect, the shield includes a stacked structure, where the shield includes a top layer, a middle layer, and a bottom layer. In one aspect, the top layer and the bottom layer may be connected to a voltage source where the positive ions can be converted into neutral particles to enhance the crystallization of the target particles onto a display.

In some embodiments, the device further includes a particle beam generator configured to generate positive ions. In one aspect, the shield is disposed between the thin film particle generator and the particle beam generator. In one aspect, the particle beam generator is disposed on and spaced apart from the display, where the thin film particles are to be deposited. The particle beam generator includes an ion extraction electrode and electron extraction electrode configured to generate neutral particles by crystalizing the target particle. By doing so, the display does not need to be heated for crystallization, and damages to the display can be minimized.

According to some embodiments, the device further includes a plasma chamber that surrounds the thin film particle generator(s) and is conned to the shield. In one aspect, inert gas is filled within the plasma chamber, where the inert gas is converted from a gas state to a plasma state. The plasma chamber ensures that the positive ions move toward the target of the thin film particle generator to enhance the generation of thin film particles. Additionally, the plasma chamber prevents the negative impurity ions from entering the shield window, and prevents contaminating the display.

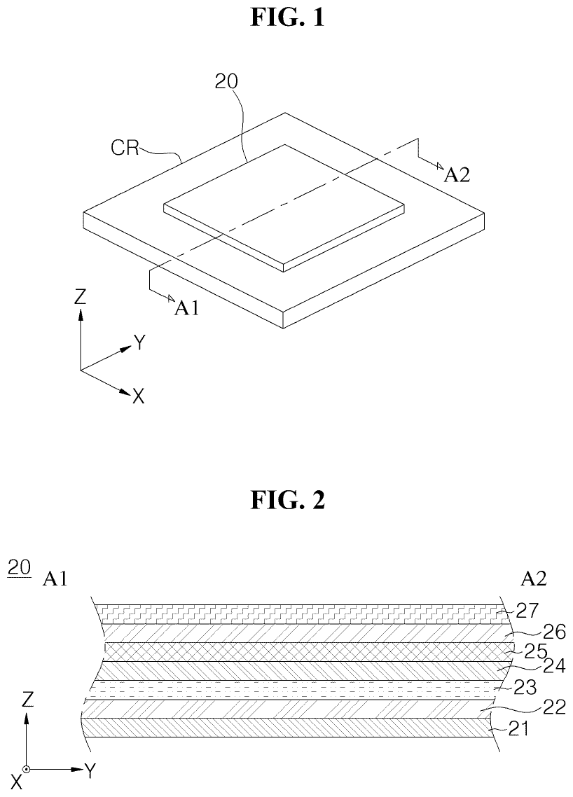

FIG. 1 illustrates a display is loaded on a carrier according to an embodiment of the present disclosure. FIG. 2 illustrates a cross section of the display illustrated in FIG. 1 taken along the cross-sectional line A1-A2 according to an embodiment of the present disclosure. In one aspect, the display may be referred to as a display panel.

Referring to FIGS. 1 and 2, a display 20 may be loaded (or provided) on a carrier CR. For example, the display 20 may be loaded on an upper surface of the carrier CR. For example, a lower surface of the display 20 may be opposite to the upper surface of the carrier CR. For example, the lower surface of the display 20 may be adjacent to (or in contact with) the upper surface of the carrier CR. The display 20 may include a stack structure.

For example, the display 20 may include at least one of a substrate 21, a TFT array 22, an insulating layer 23, a first electrode 24, an organic layer 25, a second electrode 26, or a cap layer 27. For example, the substrate 21, the TFT array 22, the insulating layer 23, the first electrode 24, the organic layer 25, the second electrode 26, and the cap layer 27 may be sequentially stacked. For example, the substrate 21 may be the lower surface of the display 20. For example, the cap layer 27 may be an upper surface of the display 20.

In an embodiment, the organic layer 25 may be an upper surface of the display 20, and the second electrode 26 may be stacked on the display 20. The display 20 may be, for example, an organic light emitting diode (OLED).

For example, the second electrode 26 may be a semitransparent electrode and may include a material having a relatively low electrical resistance and a relatively high light transmittance. For example, the second electrode 26 may be formed of an indium thin oxide (ITO) material. For example, in an example where the organic layer 25 is the upper surface of the display 20, the second electrode 26 may be stacked on (or disposed on) the display 20 by a physical deposition method.

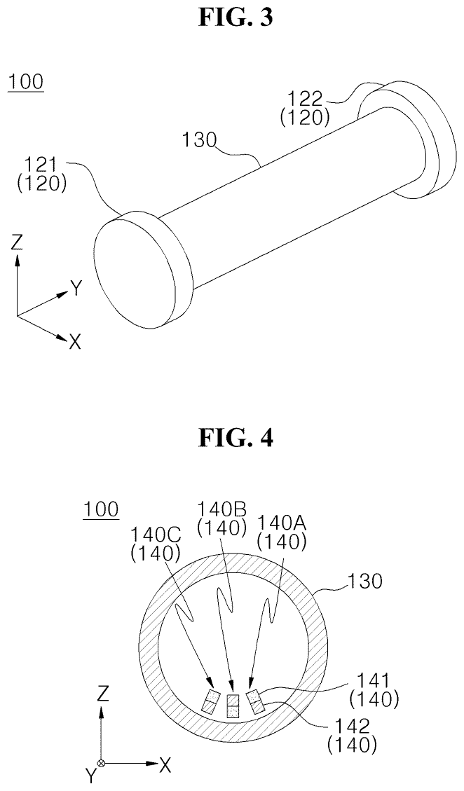

FIG. 3 illustrates a thin film particle providing module according to an embodiment of the present disclosure. FIG. 4 illustrates a cross section of the thin film particle providing module illustrated in FIG. 3.

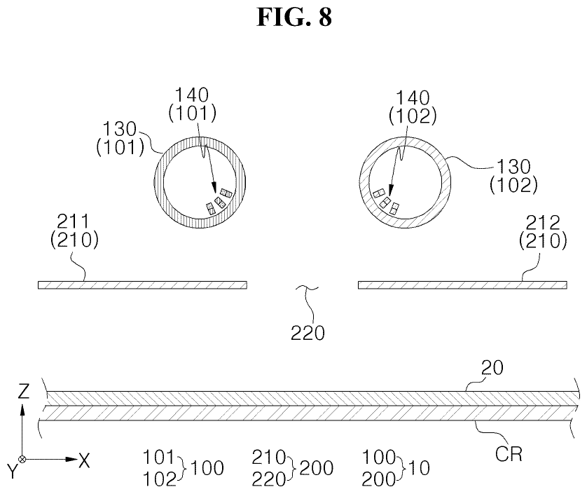

Referring to FIGS. 3 and 4, a thin film forming device 10 (see FIG. 8) according to an embodiment of the present disclosure may include a thin film particle providing module 100. The thin film particle providing module 100 may include a target 130. A target in the field of thin-film deposition refers to a component used for forming a thin film on a substrate or a layer (e.g., for forming the second electrode 26 described with reference to FIG. 2).

The target 130 may extend in a longitudinal direction. For example, the target 130 may extend in the longitudinal direction from a first end of the target 130 and lead to a second end of the target 130. For example, the longitudinal direction refers to a direction that runs along the length of an object (lor element). For example, in a cylindrical shape, the longitudinal direction extends along the length of the cylindrical shape parallel to the axis of the cylindrical shape.

The target 130 may include a hollow portion. A longitudinal direction of the hollow portion formed in the target 130 may be the longitudinal direction of the target 130. For example, the target 130 may include a shape of a pipe or a tube.

For example, an outer surface of the target 130 may be a shape of a pillar. For example, the outer surface of the target 130 may include a shape of a cylinder. For example, an inner surface of the target 130 may include a hollow portion.

The target 130 may include a material forming the second electrode 26 (see FIG. 2). For example, the target 130 may be formed of a material including indium thin oxide (ITO). For example, at least a portion of the outer surface of the target 130 may be formed of a material including ITO. For example, ITO may be applied or coated on at least a portion of the outer surface of the target 130.

At least a portion of the target 130 may be formed of an electrically conductive material. For example, the target 130 may be connected to a power source. For example, the target 130 may include an electric potential. For example, the electric potential of the target 130 may be a negative potential.

The thin film particle providing module 100 may include a mount 120. The mount 120 may be coupled to the target 130. For example, the mount 120 may be coupled to an end of the target 130. In one aspect, the mount 120 includes a first mount 121 coupled to a first end of the target 130 and a second mount 122 coupled to a second end opposite from the first end of the target 130.

For example, a first mount 121 may be rotatably coupled to a first end of the target 130. For example, a second mount 122 may be rotatably coupled to a second end of the target 130, where the second end is opposite from the first end of the target 130. The mount 120 may include or indicate at least one of the first mount 121 or the second mount 122.

For example, the target 130 may be rotatably coupled to the mount 120. For example, a motor may provide a rotational force to the target 130 via the first mount 121 or the second mount 122. When the motor provides the rotational force to the target 130, the target 130 may rotate on the mount 120.

The thin film particle providing module 100 may include a magnet 140. The magnet 140 may form a magnetic field. The magnet 140 may include, for example, at least one of a permanent magnet or an electromagnet. The magnet 140 may be disposed in the target 130. For example, the magnet 140 may be positioned in the hollow portion formed in the target 130. For example, the magnet 140 may be affixed to the mount 120. For example, when the target 130 rotates with respect to the mount 120, the magnet 140 may be fixed with respect to the mount 120.

A plurality of magnets 140 may be provided. For example, the thin film particle providing module 100 may include the plurality of magnets 140. For example, the thin film particle providing module 100 may include a first magnet 140A, a second magnet 140B, and a third magnet 140C.

The magnet 140 may include at least one of the first magnet 140A, the second magnet 140B, or the third magnet 140C. The first magnet 140A, the second magnet 140B, and the third magnet 140C may be sequentially arranged in the target 130. For example, the first magnet 140A, the second magnet 140B, and the third magnet 140C may be sequentially arranged in an azimuth direction along the inner surface of the target 130.

The magnet 140 may have two polarities. For example, the magnet 140 may include a first polarity portion 141 and a second polarity portion 142. One of the first polarity portion 141 and the second polarity portion 142 may be an N pole, and the other may be a S pole. For example, the first polarity portion 141 may be an S pole and the second polarity portion 142 may be an N pole, or vice versa.

Polarities of two adjacent magnets 140 among the plurality of magnets 140 may be arranged in opposite directions. For example, the second polarity portion 142 of the first magnet 140A may face the inner surface of the target 130, and the first polarity portion 141 of the second magnet 140B may face the inner surface of the target 130. In some cases, the polarities of the ends between two adjacent magnets may be opposite from each other. For example, the first magnet 140A may include a first polarity portion 141 adjacent to an inner surface of the target 130, and the second magnet 140B may include a second polarity portion 142 adjacent to an inner surface of the target 130.

For example, the first polarity portion 141 of the second magnet 140B may face the inner surface of the target 130, and the second polarity portion 142 of the third magnet 140C may face the inner surface of the target 130. In some cases, the configuration of the first magnet 140A and the configuration of the third magnet 140C may be the same.

The magnet 140 may form a magnetic field or a magnetic flux outside the target 130. Through the polarity arrangement of the plurality of magnets 140, a magnetic cusp may be formed on the outer surface of the target 130.

When positive ions are located outside the target 130, the positive ions may move toward the target 130 by an electric field formed by the electric potential of the target 130. Ions located outside the target 130 may be affected by the magnetic field formed by the magnet 140. For example, ions located outside the target 130 may move around magnetic force lines formed by the magnet 140.

For example, the positive ions may be incident toward a portion of the outer surface of the target 130 facing the magnet 140. When the positive ions are incident on the outer surface of the target 130, particles of the target 130 may be ejected by energy of the incident positive ions.

The particles of the target 130 ejected from the outer surface of the target 130 may be “thin film particles” deposited on the display 20 (see FIG. 1) in a state where the organic layer 25 (see FIG. 2) forms the upper surface of the display 20 (see FIG. 2).

As the target 130 rotates, a portion of the outer surface of the target 130 through which the magnetic force lines formed by the magnet 140 pass may vary over time. For example, as the target 130 rotates, the particles may be evenly ejected from the outer surface of the target 130.

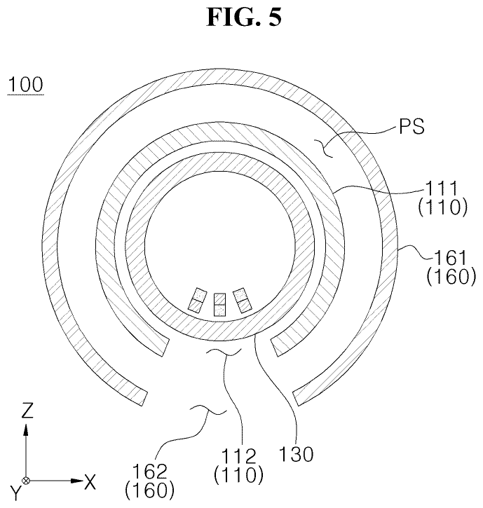

FIG. 5 illustrates a case and a plasma housing are coupled to a target illustrated in FIG. 4 according to an embodiment of the present disclosure. Referring to FIGS. 4 and 5, the thin film particle providing module 100 may include a casing 110. The casing 110 may include a casing body 111 and a casing window 112. The casing body 111 may extend in a longitudinal direction.

For example, the longitudinal direction of the casing body 111 may be the longitudinal direction of the target 130. For example, the casing body 111 may extend in the longitudinal direction from a first end of the casing body 111 to a second end of the casing body 111. In some cases, the inner surface of the casing 110 may be substantially parallel to the outer surface of the target 130. In some cases, the casing 110 may surround the target 130.

The casing body 111 may be coupled to or connected to the mount 120 (see FIG. 3). For example, the first end of the casing body 111 may be coupled to the first mount 121 (see FIG. 3), and the second end of the casing body 111 may be coupled to the second mount 122, (see FIG. 3).

The casing body 111 may form a hollow portion therein. A longitudinal direction of the hollow portion formed in the casing body 111 may be the longitudinal direction of the casing body 111.

For example, the casing body 111 may surround the target 130. For example, the target 130 may be located in the hollow portion of the casing body 111. For example, an inner surface of the casing body 111 may face the outer surface of the target 130.

For example, the casing 110 may include a casing window 112. The casing window 112 may be an opening formed in the casing body 111. For example, the casing window 112 may be connected to the inner surface and an outer surface of the casing body 111. For example, the hollow portion formed in the casing body 111 may be opened in a radial direction (or radially) through the casing window 112.

The magnet 140 and the casing window 112 may be arranged in the radial direction. For example, the magnetic force lines or magnetic flux formed by the magnet 140 may penetrate the target 130 and located at the casing window 112.

The thin film particle providing module 100 may include a plasma housing 160. The plasma housing 160 may include a plasma housing body 161 and a plasma housing window 162. A longitudinal direction of the plasma housing body 161 may be the longitudinal direction of the casing body 111. In one aspect, the surface of the plasma housing 160 may be substantially parallel to the surface of the casing 110 or the target 130. In one aspect, the plasma housing 160 may surround the casing 110 and the target 130.

The plasma housing body 161 may extend in the longitudinal direction. For example, the plasma housing body 161 may extend in the longitudinal direction from a first end of the plasma housing body 161 to a second end of the plasma housing body 161.

The plasma housing body 161 may be coupled to or connected to the mount 120 (see FIG. 3). For example, the first end of the plasma housing body 161 may be coupled to the first mount 121 (see FIG. 3), and the second end of the plasma housing body 161 may be coupled to the second mount 122 (see FIG. 3).

The plasma housing body 161 may include a hollow portion therein. A longitudinal direction of the hollow portion formed in the plasma housing body 161 may be the longitudinal direction of the plasma housing body 161.

For example, the plasma housing body 161 may surround the casing 110. For example, the casing 110 may be located in the hollow portion formed in the plasma housing body 161. For example, an inner surface of the plasma housing body 161 may face an outer surface of the casing 110. For example, the inner surface of the plasma housing body 161 may be spaced apart from the outer surface of the casing body 111. For example, the inner surface of the plasma housing body 161 may be radially spaced apart from the outer surface of the casing body 111.

For example, a plasma space PS may be a space formed between the inner surface of the plasma housing body 161 and the outer surface of the casing body 111. Plasma may be formed in the plasma space PS. For example, an inert gas may be injected into the plasma space PS. For example, the inert gas injected into the plasma space PS may include at least one of helium (He), argon (Ar), or neon (Ne).

The inert gas injected into the plasma space PS may be converted into plasma by an electric field or electromagnetic wave energy. When the inert gas is converted into plasma, positive ions may be generated. For example, positive argon ions may be formed in the plasma space PS.

The plasma housing 160 may include a plasma housing window 162. The plasma housing window 162 may be an opening formed in the plasma housing body 161. For example, the plasma housing window 162 may be connected to the inner surface and an outer surface of the plasma housing body 161. For example, the plasma space PS may be radially opened to the outside through the plasma housing window 162.

The magnet 140, the casing window 112, and the plasma housing window 162 may be sequentially arranged. For example, the magnet 140, the casing window 112, and the plasma housing window 162 may be arranged sequentially and radially. For example, the magnet 140, the casing window 112, and the plasma housing window 162 may be aligned radially (e.g., towards or away from a center of the target 130.

Positive inert particle ions (e.g., positive argon ions) formed in the plasma space PS may move toward the target 130 based on the electric field formed by the target 130. In one aspect, the positive inert particle ions may move towards the target 130 through the casing window 112.

The positive inert particle ions moving toward the target 130 may be bound by the magnetic force lines or the magnetic flux formed by the magnet 140 and may be gathered at a certain point of the target 130 to strike the target 130. Hence, target particles may be ejected from the target 130.

The target particles ejected from the target 130 may sequentially pass through the casing window 112 and the plasma housing window 162. The target particles may move toward the display 20 illustrated in FIG. 1. In some embodiments, the casing window 112 and the plasma housing window 162 may be disposed and directed at an upper surface of the display 20.

In some cases, negative impurity ions may be generated at the target 130. For example, the negative impurity ions may include negative oxygen ions. In some cases, when the negative impurity ions reach a display, the quality of the display may deteriorate.

A radiation angle of the target particles generated from the outer surface of the target 130 may be greater than a radiation angle of the negative impurity ions generated from the outer surface of the target 130. For example, the radiation angle may be referred to as an angle at which the ions are emitted from the outer surface of the target 130. For example, a high radiation angle represents a wide (or large) angular range, whereas a low radiation angle represents a narrow (or smaller) angular range.

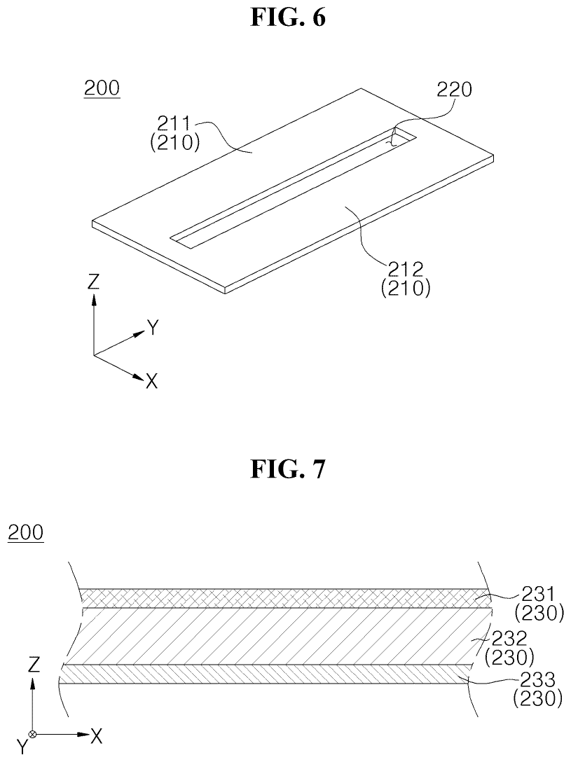

According to some embodiments, a shield 200 (see FIG. 6) that suppresses the negative impurity ions from reaching the display 20 and allows the target particles to reach the display 20 may be implemented.

FIG. 6 illustrates a shield according to an embodiment of the present disclosure. FIG. 7 illustrates a cross section of the shield illustrated in FIG. 6. Referring to FIGS. 6 and 7, the thin film forming device 10 (see FIG. 8) may include the shield 200. The shield 200 may include a shape of a plate. In one aspect, the shield 200 includes a shield wing 210 and a shield window 220.

For example, the shield 200 may include two surfaces. For example, the shield 200 may form a first surface and a second surface. The first surface of the shield 200 may face thin film particle generators 101 and 102 (see FIG. 8). The second surface of the shield 200 may face the display 20 (see FIG. 8). In some cases, the first surface may be referred to as an upper surface of the shield 200 and the second surface may be referred to as the lower surface of the shield 200.

The shield 200 may include a shield wing 210 and a shield window 220. For example, the shield 200 may include a first shield wing 211 and a second shield wing 212. The shield wing 210 may include at least one of the first shield wing 211 or the second shield wing 212.

The shield window 220 may be an opening formed in the shield 200. The shield window 220 may be located between the first shield wing 211 and the second shield wing 212. The shield window 220 may form a shape extending in the longitudinal direction. The longitudinal direction of the shield window 220 may be the longitudinal direction of the target 130 (see FIG. 3).

A width direction of the shield window 220 may be parallel to a direction from the first shield wing 211 to the second shield wing 212. For example, the first shield wing 211 and the second shield wing 212 may be arranged in the width direction of the shield window 220. For example, the first shield wing 211 and the second shield wing 212 may be arranged in a direction crossing the shield window 220.

For example, the first shield wing 211, the shield window 220, and the second shield wing 212 may be sequentially arranged. For example, the first shield wing 211, the shield window 220, and the second shield wing 212 may be sequentially arranged in the width direction of the shield window 220.

The first shield wing 211 and the second shield wing 212 may be connected at an end of the shield window 220. For example, the first shield wing 211 and the second shield wing 212 may be spaced apart from each other. In some cases, the shield window 220 may include a slit shape in a plan view.

The shield 200 may be formed in a stacked structure. For example, the shield 200 may include a top layer 231, a middle layer 232, and a bottom layer 233. The top layer 231 may have a shape of a sheet. A surface of the top layer 231 may form the upper surface of the shield 200.

The shield 200 may include a middle layer 232. For example, the middle layer 232 may have a shape of a sheet. A surface of the middle layer 232 may be coupled to another surface of the top layer 231. For example, an upper surface of the middle layer 232 may be disposed on a lower surface of the top layer 231.

The shield 200 may include a bottom layer 233. For example, the bottom layer 233 may have a shape of a sheet. A first surface of the bottom layer 233 may be coupled to a surface of the middle layer 232. A second surface of the bottom layer 233 may form the lower surface of the shield 200. For example, the lower surface of the middle layer 232 may be disposed on an upper surface of the bottom layer 233. In some aspects, the top layer 231, the middle layer 232, and the bottom layer 233 may be sequentially stacked.

The shield layer 230 may include at least one of the top layer 231, the middle layer 232, or the bottom layer 233. The top layer 231, the middle layer 232, and the bottom layer 233 may be sequentially stacked. In some cases, each of the top layer 231, the middle layer 232, and the bottom layer 233 may be formed of different material. In some cases, each of the top layer 231, the middle layer 232, and the bottom layer 233 may be formed of the same material.

FIG. 8 is a cross-sectional view illustrating that a thin film forming device is disposed on the display illustrated in FIG. 1 according to an embodiment of the present disclosure.

Referring to FIGS. 1 to 8, the thin film particle providing module 100 may include the thin film particle generators 101 and 102. The thin film particle generators 101 and 102 may include at least one of the first thin film particle generator 101 or the second thin film particle generator 102. In some embodiments, the thin film particle providing module 100 includes one or more thin film particle generators.

A plane formed by the display 20 may be a horizontal plane. A longitudinal direction (e.g., the Y direction) of the thin film particle generators 101 and 102 may be parallel to the horizontal plane. A direction in which the first thin film particle generator 101 and the second thin film particle generator 102 are arranged may be parallel to the horizontal plane (e.g., the XY plane).

A vertical direction may be a direction perpendicular to the horizontal plane (e.g., the Z direction). For example, the thin film particle generators 101 and 102, the shield 200, and the display 20 may be arranged in the vertical direction.

For example, a gap between the first thin film particle generator 101 and the shield window 220, or the second thin film particle generator 102 and the shield window 220 may be arranged in the vertical direction.

The thin film particle generators 101 and 102 may include the target 130 and the magnet 140. The shield wing 210 may be disposed between the thin film particle generators 101 and 102 and the display 20. For example, the first shield wing 211 may be disposed between the first thin film particle generator 101 and the display 20. For example, the second shield wing 212 may be disposed between the second thin film particle generator 102 and the display 20.

The magnet 140 of the first thin film particle generator 101 may be directed at a direction towards the second shield wing 212. The magnet 140 of the second thin film particle generator 102 may be directed at a direction towards the first shield wing 211.

For example, a rotation axis of the target 130 of the first thin film particle generator 101, the magnet 140 of the first thin film particle generator 101, and the second shield wing 212 may be sequentially arranged. For example, a rotation axis of the target 130 of the second thin film particle generator 102, the magnet 140 of the second thin film particle generator 102, and the first shield wing 211 may be sequentially arranged.

Through the above-described structure, at least a portion of negative impurity ions generated from the thin film particle generators 101 and 102 may be emitted to the shield wing 210. As a result, the shield 200 can suppress the negative impurity ions from being emitted to the display 20. For example, the positive ions generated from the thin film particle generator 101 may be emitted onto the display 20 through the shield window 220. Additionally, the negative ions generated from the thin film particle generator 101 may be blocked by the first shield wing 211 and the second shield wing 212 of the shield wing 210. Similarly, the positive ions generated from the thin film particle generator 102 may be emitted onto the display 20 through the shield window 220. Additionally, the negative ions generated from the thin film particle generator 102 may be blocked by the first shield wing 211 and the second shield wing 212 of the shield wing 210.

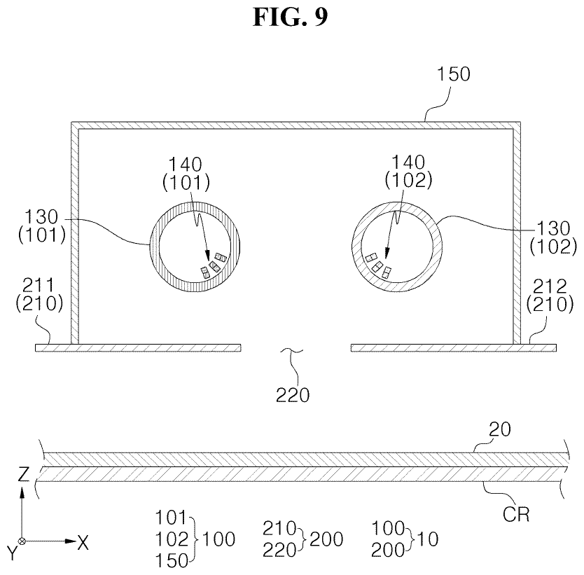

FIG. 9 illustrates that a plasma chamber including the thin film particle providing module illustrated in FIG. 8. Referring to FIGS. 1 to 9, the thin film particle providing module 100 may include a plasma chamber 150. The plasma chamber 150 may surround the thin film particle generators 101 and 102.

The plasma chamber 150 may be connected to or coupled to the shield wing 210. For example, the plasma chamber 150 and the shield wing 210 may surround the thin film particle generators 101 and 102. For example, a hollow portion formed by the plasma chamber 150 and the shield wing 210 may communicate with the outside through the shield window 220.

An inert gas may be injected into the inside of the plasma chamber 150. The inert gas injected into the hollow portion formed in the plasma chamber 150 may include, for example, at least one of helium (He), argon (Ar), or neon (Ne).

The inert gas injected into the hollow portion of the plasma chamber 150 may be converted into plasma by an electric field or electromagnetic wave energy. When the inert gas is converted into plasma, positive ions may be generated. For example, positive argon ions may be formed in the plasma chamber 150. The positive ions formed in the plasma chamber 150 may move toward the target 130 of the thin film particle generators 101 and 102. In some cases, the electric field or electromagnetic wave energy may be generated by the magnets 140 of the thin film particle generators 101 and 102.

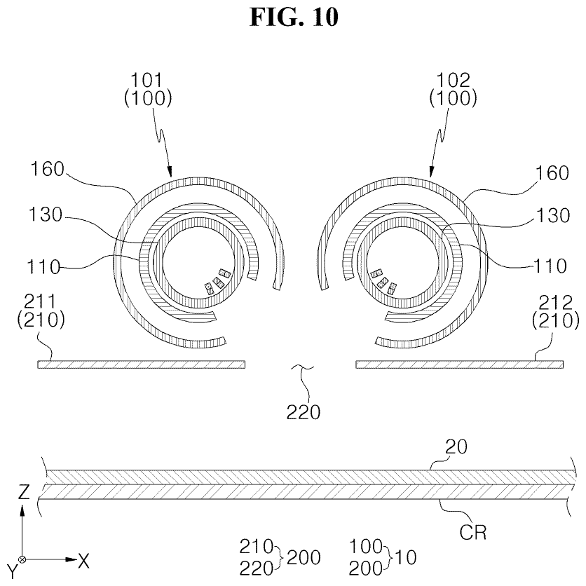

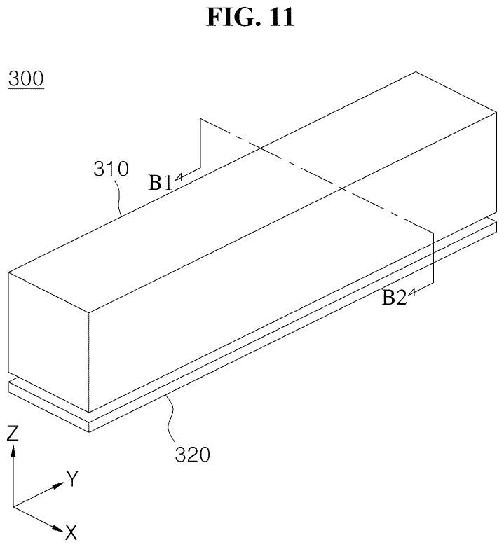

FIG. 10 illustrates a thin film particle generator including a plasma housing according to an embodiment of the present disclosure.

Referring to FIGS. 1 to 8 and FIG. 10, the thin film particle generators 101 and 102 may include a plasma housing 160. Positive inert ions formed in the plasma space PS may be incident on the target 130. In one aspect, the plasma space PS may be formed between an inner surface of the plasma housing 160 and an outer surface of the casing 110 as described with reference to FIG. 5.

The outer surface of a portion of the target 130 of the first thin film particle generator 101 adjacent to the magnet 140 of the first thin film particle generator 101 may face the second shield wing 212 through the plasma housing window 162 of the first thin film particle generator 101. Similarly, the outer surface of a portion of the target 130 of the second thin film particle generator 102 adjacent to the magnet 140 of the second thin film particle generator 102 may face the first shield wing 211 through the plasma housing window 162 of the second thin film particle generator 102.

Referring to FIGS. 1 to 10, target particles generated from the thin film particle generators 101 and 102 may be emitted to the display 20. The target particles emitted to the display 20 may be crystallized.

For example, when energy is applied to the target particles emitted to the display 20, the target particles emitted to the display 20 may be crystallized. A method of crystallizing the target particles emitted to the display is by heating a display. However, in some cases, this method may damage the display.

In some cases, a method of crystalizing the emitted particle includes colliding neutral particles with the target particles emitted to a display. For example, while target particles is emitted to a display, neutral particles may also be emitted to the display. By using this method of crystallization, damages to the display can be avoided. Further detail on the generating the neutral particles are described with reference to FIGS. 11-15.

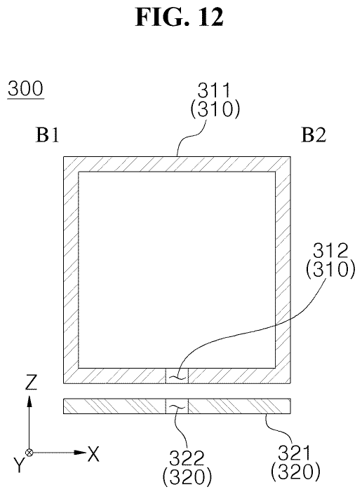

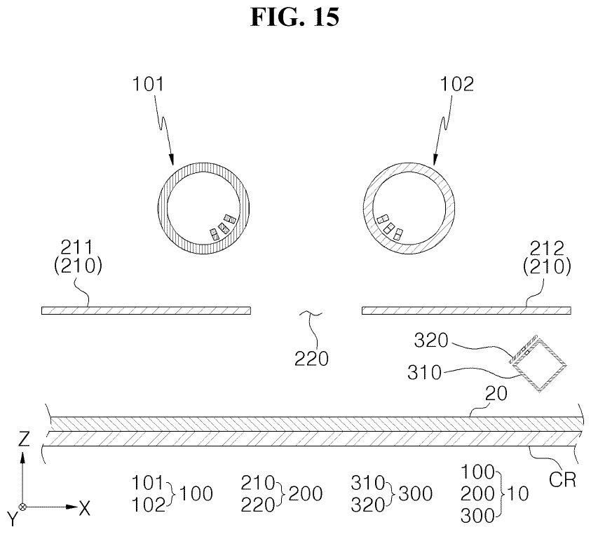

FIG. 11 illustrates a particle beam generator according to an embodiment of the present disclosure. FIG. 12 illustrates a cross section of the particle beam generator illustrated in FIG. 11 taken along cross-sectional line B1-B2. Referring to FIGS. 11 and 12, the thin film forming device 10 (see FIG. 15) may include a particle beam generator 300. The particle beam generator 300 may include a particle beam chamber 310 and an ion extraction electrode 320.

The particle beam chamber 310 may include a particle beam chamber body 311. The particle beam chamber body 311 may extend in the longitudinal direction. For example, the particle beam chamber body 311 may be parallel to the target 130 (see FIG. 3).

For example, the longitudinal direction of the particle beam chamber body 311 may be the longitudinal direction of the target 130 (see FIG. 3). For example, the particle beam chamber body 311 may extend in the longitudinal direction from a first end of the particle beam chamber body 311 to a second end of the particle beam chamber body 311.

The particle beam chamber body 311 may include a hollow portion therein. A longitudinal direction of the hollow portion formed in the particle beam chamber body 311 may be the longitudinal direction of the particle beam chamber body 311.

The particle beam chamber 310 may include an ion slit 312. The ion slit 312 may be a slit formed in the particle beam chamber body 311. A longitudinal direction of the ion slit 312 may be the longitudinal direction of the particle beam chamber body 311.

For example, the ion slit 312 may be parallel to the shield window 220 (see FIG. 15). For example, the longitudinal direction of the ion slit 312 may be the longitudinal direction of the shield window 220 (see FIG. 15).

A gas may be injected into the inside of the particle beam chamber 310. For example, an inert gas may be injected into the inside of the particle beam chamber 310. The gas injected into the inside of the particle beam chamber 310 may include, for example, at least one of argon (Ar), helium (He), or neon (Ne).

Inside the particle beam chamber 310, energy may be applied to convert the inert gas from a gas state into a plasma state. For example, positive ions and electrons may be distributed inside the particle beam chamber 310.

The particle beam generator 300 may include an ion extraction electrode 320. The ion extraction electrode 320 may include an ion extraction electrode body 321 and an ion extraction electrode slit 322. A surface of the ion extraction electrode body 321 may face a surface of the particle beam chamber body 311. For example, the ion extraction electrode 320 may be disposed adjacent to the surface including the ion slit of the particle beam chamber 310.

The ion extraction electrode 320 may include an ion extraction electrode slit 322. The ion extraction electrode slit 322 may be a slit formed in the ion extraction electrode body 321.

The ion extraction electrode slit 322 may face the ion slit 312. The ion extraction electrode slit 322 may be arranged side by side with the ion slit 312. For example, a longitudinal direction of the ion extraction electrode slit 322 may be the longitudinal direction of the ion slit 312.

An electric field may be formed between the ion extraction electrode body 321 and the particle beam chamber body 311. For example, an electric potential of the particle beam chamber body 311 may be higher than an electric potential of the ion extraction electrode body 321. Hence, positive ions located inside the particle chamber body 311 may be extracted to the outside by sequentially passing through the ion slit 312 and the ion extraction electrode slit 322.

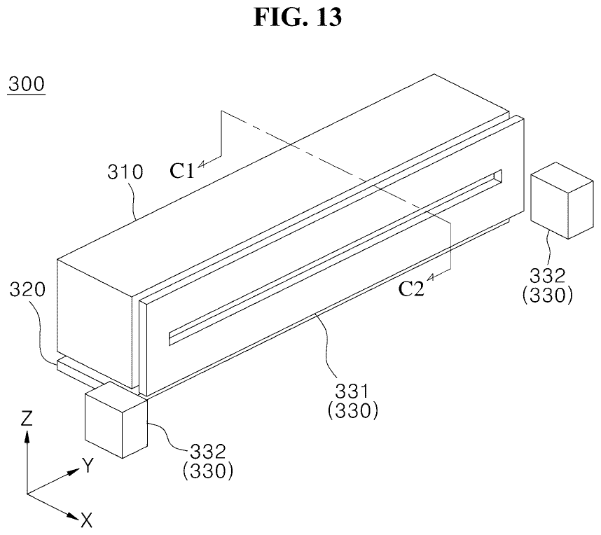

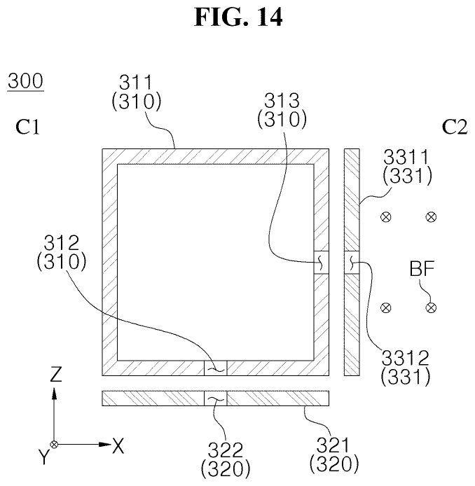

FIG. 13 illustrates an electron extraction electrode and the particle beam generator illustrated in FIG. 11. FIG. 14 illustrates a cross section of the particle beam generator illustrated in FIG. 13 taken along cross-sectional line C1-C2.

Referring to FIGS. 13 and 14, the particle beam chamber 310 may include an electron slit 313. For example, the ion slit 312 may be formed on a first side of the particle beam chamber body 311, and the electron slit 313 may be formed on a second side of the particle beam chamber body 311. In some embodiments, the first side and the second side of the particle beam chamber may be perpendicular to each other. In some embodiments, the first side and the second side of the particle beam chamber may be parallel and opposite to each other. For example, the ion slit 312 may be formed on a first side of the particle beam chamber body 311 and is perpendicular to the electron slit 313 formed on a second side of the particle beam chamber body 311.

The electron slit 313 may be a slit formed in the particle beam chamber body 311. The electron slit 313 may be spaced apart from the ion slit 312. The electron slit 313 may be arranged side by side with the ion slit 312. For example, a longitudinal direction of the electron slit 313 may be the longitudinal direction of the ion slit 312. In some cases, the shape of the ion slit 312 may be substantially the same as the shape of the electron slit 313.

The particle beam generator 300 may include an electron generator 330. The electron generator 330 may include an electron extraction electrode 331. The electron extraction electrode 331 may include an electron extraction electrode body 3311 and an electron extraction electrode slit 3312.

The electron extraction electrode body 3311 may face the other side of the particle beam chamber body 311. For example, a surface of the electron extraction electrode body 3311 may be adjacent and opposite to a surface of the particle beam chamber body 311 that includes the surface with the electron slit 313. An electron extraction electrode slit 3312 may be a slit formed in the electron extraction electrode body 3311.

The electron extraction electrode slit 3312 may be arranged adjacent to the electron slit 313. For example, a longitudinal direction of the electron extraction electrode slit 3312 may be the longitudinal direction of the electron slit 313. In some cases, the electron extraction electrode slit 3312 may be spaced apart from the electron slit 313.

An electric field may be formed between the electron extraction electrode body 3311 and the particle beam chamber body 311. For example, an electric potential of the electron extraction electrode body 3311 may be higher than the electric potential of the particle beam chamber body 311.

For example, the electric potential of the particle beam chamber body 311 may be higher than the electric potential of the ion extraction electrode body 321 and lower than the electric potential of the electron extraction electrode body 3311.

The electron generator 330 may include an electron guide segment 332. The electron guide segment 332 may form a magnetic field BF. For example, the electron generator 330 may include a pair of electron guide segments 332.

For example, the electron generator 330 may include a pair of electron guide segments 332. A direction of the magnetic field BF formed by the pair of electron guide segments 332 may be the longitudinal direction of the electron extraction electrode slit 3312 (e.g., the Y direction).

For example, the pair of electron guide segments 332 may be a pair of magnets having opposite polarities on the surfaces that are opposite from each other. For example, each of the pair of electron guide segments 332 may include a coil wound at least once.

For example, an electron extraction direction may be a direction from the particle beam chamber 310 toward the electron extraction electrode 331. For example, the electron extraction direction may be a direction from the electron slit 313 toward the electron extraction electrode slit 3312. An electron extraction unit vector may be a vector which has a magnitude of 1 and a direction towards the electron extraction direction.

For example, an ion extraction direction may be a direction from the particle beam chamber 310 toward the ion extraction electrode 320. For example, the ion extraction direction may be a direction from the ion slit 312 toward the ion extraction electrode slit 322. An ion extraction unit vector may be a vector which has a magnitude of 1 and a direction towards the ion extraction direction.

A direction of the magnetic field BF formed by the electron guide segment 332 may be a direction of a vector formed by a cross product of the electron extraction unit vector and the ion extraction unit vector.

Negatively charged particles located inside the particle beam chamber 310 may sequentially pass through the electron slit 313 and the electron extraction electrode slit 3312. The negatively charged particles passing through the electron extraction electrode slit 3312 may be bent in the ion extraction direction by receiving the Lorentz force due to the magnetic field BF.

The degree to which a path is bent by the magnetic field BF may be inversely proportional to the mass of the negatively charged particles. For example, the degree to which a path of an electron with a relatively small mass is bent may be greater than the degree to which a path of a negative ion with a relatively large mass is bent.

Therefore, electrons passing through the electron extraction electrode slit 3312 may be bent by the magnetic field BF and move to intersect with positive ions extracted from the particle beam chamber 310. Hence, the positive ions extracted from the particle beam chamber 310 may meet the electrons and be converted into neutral particles.

In some cases, when negative ions passing through the electron extraction electrode slit 3312 are bent by the magnetic field BF and move, the negative ions may be discarded without intersecting with the positive ions extracted from the particle beam chamber 310.

FIG. 15 illustrates the particle beam generator and the thin film forming device according to an embodiment of the present disclosure.

Referring to FIGS. 8, 11, 12, and 15, the particle beam generator 300 may be disposed and parallel to the thin film particle generators 101 and 102. For example, the longitudinal direction of the particle beam generator 300 may be the same as the longitudinal direction of the target 130.

The particle beam generator 300 may be disposed between the shield 200 and the display 20. For example, the particle beam generator 300 may obliquely face the shield 200. For example, the particle beam generator 300 may be disposed at an angle with respect to the shield wing 210. For example, a surface of the particle beam generator 300 might not be parallel or perpendicular to the lower surface of the shield wing 210.

For example, positive ions extracted from the particle beam generator 300 may be obliquely incident on the shield wing 210. The positive ions incident on the shield wing 210 may be reflected from the shield wing 210. The positive ions reflected from the shield wing 210 may move toward the display 20.

The positive ions incident on the shield wing 210 may exchange electrons with the shield wing 210. For example, in a process of reflecting the positive ions incident on the shield wing 210 from the shield wing 210, the positive ions may be converted into neutral particles by receiving electrons from the shield wing 210.

The converted neutral particles may move toward the display 20. The neutral particles may provide energy to the target particles emitted to the upper surface of the display 20. As a result, the target particles may be crystallized to form the second electrode 26 (see FIG. 2). In the example shown in FIG. 15, the particle beam generator 300 is disposed between the thin film particle generator 102 and the display 20. However, embodiments are not limited hereto. For example, the particle beam generator 300 may be disposed between the thin film particle generator 101 and the display 20. In some embodiments, one or more particle beam generators may be disposed between the shield wing 210 and the display 20.

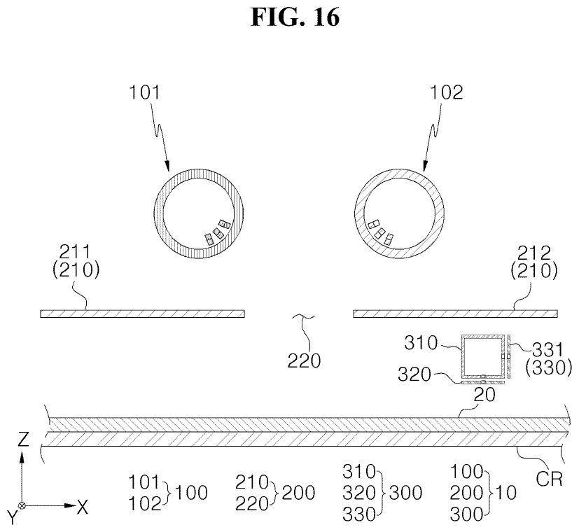

FIG. 16 illustrates that the particle beam generator and the thin film forming device according to an embodiment of the present disclosure. Referring to FIGS. 8, 13, 14, and 16, the particle beam generator 300 may be parallel to the thin film particle generators 101 and 102. For example, the longitudinal direction of the particle beam generator 300 may be the longitudinal direction of the target 130.

Positive ions extracted from the particle beam generator 300 may move toward the display 20. The positive ions moving toward the display 20 may meet electrons which are extracted from the particle beam generator 300 and move along a bent path. The positive ions moving toward the display 20 may meet the electrons from the electron generator 330 and are converted into neutral particles. The converted neutral particles may transfer energy to the target particles emitted to the display 20.

In some embodiments, side surfaces of the particle beam generator 300 may be substantially parallel to the lower surface of the shield wing 210 or the upper surface of the display 20. For example, the ion extraction electrode 320 may be disposed between the shield wing 210 and the display 20. A lower surface of the ion extraction electrode 320 may be substantially parallel and opposite to an upper surface of the display 20. In some cases, the positive ions are emitted from the ion extraction electrode 320 to the display.

According to some embodiments, the electrons are emitted from the electron generator 330. The electrons may be interacted with the positive ions emitted from the ion extraction electrode 320 to form neutral particles. In one aspect, the neutral particles may be used to crystalize the target particle generated from the thin film particle generators 101 and 102 to crystalize the emitted particle. Accordingly, damage to the display 20 can be reduced or avoided.

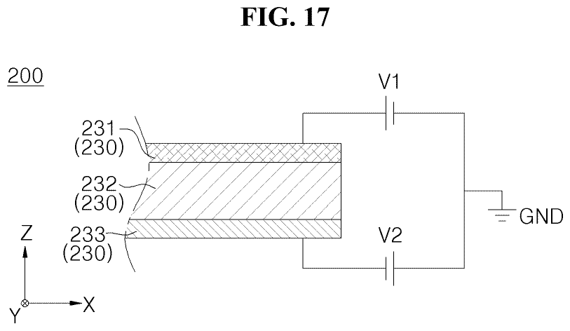

FIG. 17 illustrates a power source connected to the shield according to an embodiment of the present disclosure. Referring to FIGS. 15 and 17, the top layer 231 of the shield 200 and the bottom layer 233 of the shield may be formed of an electrically conductive material. The middle layer 232 of the shield 200 may be formed of an electrically insulating material. The top layer 231 and the bottom layer 233 may form an electric circuit.

For example, the top layer 231 may be connected to a first voltage source V1, which provides a positive electric potential to the top layer 231. In some cases, when negative oxygen ions collide with the top layer 231, the negative oxygen ions may be converted into oxygen molecules through electron exchange in the top layer 231.

For example, the bottom layer 233 may be connected to a second voltage source V2, which provides a negative electric potential to the bottom layer 233. In a process in which positive ions extracted from the particle beam generator 300 are incident on the bottom layer 233 and reflected, the positive ions may receive electrons from the bottom layer 233 and be converted into neutral particles.

Referring to FIGS. 1 to 17, the electric potential of the ion extraction electrode 320 may be higher than the electric potential of the particle beam chamber 310. For example, the electric potential of the ion extraction electrode 320 may be positive, and the electric potential of the particle beam chamber 310 may be negative. In this case, negative ions may be extracted from the ion extraction electrode 320.

The negative ions extracted from the ion extraction electrode 320 may move toward the display 20. A laser beam may intersect with the negative ions moving toward the display 20. For example, a laser may emit the laser beam to the negative ions that are extracted from the ion extraction electrode 320.

When the negative ions interact with the laser beam, electrons attached to the negative ions may fall off. For example, the negative ions may meet the laser beam and be converted into neutral particles. Accordingly, the neutral particles may move toward the display 20, and energy may be transferred to the target particles emitted to the display 20.

What is claimed is:

1. A thin film forming device comprising:
a thin film particle generator including a target, wherein the target is configured to emit thin film particles;
a particle beam generator configured to generate positive ions; and
a shield disposed between the thin film particle generator and the particle beam generator,
wherein the shield includes a first shield wing, a shield window, and a second shield wing, the shield window includes an opening formed between the first shield wing and the second shield wing, and the shield window is configured to receive the thin film particles, and
wherein the particle beam generator is directed toward at least one of the first shield wing or the second shield wing.

2. The thin film forming device of claim 1, wherein:
the particle beam generator is configured to emit the positive ions at an angle toward at least one of the first shield wing or the second shield wing.

3. The thin film forming device of claim 1, wherein the particle beam generator includes:
a particle beam chamber including a particle beam chamber body and an ion slit formed in the particle beam chamber body; and
an ion extraction electrode including an ion extraction electrode body and an ion extraction electrode slit formed in the ion extraction electrode body, wherein the ion extraction electrode body is opposite from the particle beam chamber body.

4. The thin film forming device of claim 3, wherein:
the ion extraction electrode slit and the ion slit are opposite from each other and are parallel to the target.

5. The thin film forming device of claim 3, wherein:
an electric potential of the ion extraction electrode is lower than an electric potential of the particle beam chamber.

6. The thin film forming device of claim 1, wherein:
the particle beam generator is configured to generate neutral particles by combining the positive ions and electrons, and
wherein the positive ions incident on the first shield wing or the second shield wing are reflected.

7. The thin film forming device of claim 1, wherein the thin film particle generator includes:
a mount rotatably coupled to the target;
a magnet disposed in a hollow portion formed in the target, wherein the magnet is connected to the mount;
a casing comprises a casing body surrounding the target and a casing window formed in the casing body; and
a plasma housing comprises a plasma housing body surrounding the casing and a plasma housing window formed in the plasma housing body.

8. The thin film forming device of claim 7, wherein:
the casing window and the plasma housing window are aligned with the magnet.

9. The thin film forming device of claim 8, wherein:
an inner surface of the plasma housing body and an outer surface of the casing body face each other and are spaced apart from each other to form a plasma space.

10. The thin film forming device of claim 1, wherein:
the thin film particle generator includes a first thin film particle generator and a second thin film particle generator spaced apart from each other,
wherein the first shield wing is disposed below the first thin film particle generator, and
wherein the second shield wing is disposed below the second thin film particle generator.

11. The thin film forming device of claim 10, further comprising:
a plasma chamber configured to generate plasma, wherein the plasma chamber surrounds the first thin film particle generator and the second thin film particle generator.

12. The thin film forming device of claim 1, wherein:
a top layer of the first shield wing is opposite from the thin film particle generator,
a bottom layer of the first shield wing is opposite from the particle beam generator, and
the top layer and the bottom layer are spaced apart from each other.

13. The thin film forming device of claim 12, wherein:
the top layer includes a positive electric potential and the bottom layer includes a negative electric potential.

14. A thin film forming device comprising:
a thin film particle generator including a target, wherein the target is configured to emit thin film particles;
a particle beam generator configured to generate positive ions; and
a shield disposed between the thin film particle generator and the particle beam generator,
wherein the shield includes a first shield wing, a shield window, and a second shield wing, the shield window includes an opening formed between the first shield wing and the second shield wing, and the shield window is configured to receive the thin film particles,
wherein the particle beam generator includes:
a particle beam chamber including a particle beam chamber body; and
an ion extraction electrode including an ion extraction electrode body opposite from a side surface of the particle beam chamber body, and
wherein the particle beam chamber is disposed between the shield and the ion extraction electrode.

15. The thin film forming device of claim 14, wherein:
the particle beam chamber includes an ion slit formed in the particle beam chamber body, and
wherein the ion extraction electrode includes an ion extraction electrode slit formed in the ion extraction electrode body, and the ion extraction electrode slit is opposite from the ion slit.

16. The thin film forming device of claim 15, wherein:
an electric potential of the ion extraction electrode is lower than an electric potential of the particle beam chamber,
wherein the particle beam generator includes:
an electron extraction electrode including an electron extraction electrode body opposite and spaced apart from a first side of the particle beam chamber; and an electron extraction electrode slit formed in the electron extraction electrode body; and
an electron guide segment configured to generate a magnetic field, and
wherein the particle beam chamber includes an electron slit formed in the first side of the particle beam chamber body.

17. The thin film forming device of claim 16, wherein:
the electron extraction electrode slit and the electron slit are aligned, and
wherein an electric potential of the electron extraction electrode is higher than the electric potential of the particle beam chamber.

18. The thin film forming device of claim 17, wherein:
the magnetic field formed by the electron guide segment is located on an opposite side of the particle beam chamber with respect to the electron extraction electrode.

19. A thin film forming device comprising:
a thin film particle generator including a target, wherein the target is configured to emit thin film particles;
a particle beam generator configured to generate negative ions;
a shield disposed between the thin film particle generator and the particle beam generator; and
a laser configured to emit a laser beam to the negative ions to generate neutral particles,
wherein the shield includes a first shield wing, a shield window, and a second shield wing; the shield window includes an opening formed between the first shield wing and the second shield wing, and the shield window is configured to receive the thin film particles.

20. The thin film forming device of claim 19, wherein the particle beam generator includes:
a particle beam chamber including a particle beam chamber body and an ion slit formed in the particle beam chamber body; and
an ion extraction electrode including an ion extraction electrode body opposite and spaced apart from a side of the particle beam chamber body; and
an ion extraction electrode slit formed in the ion extraction electrode body,
wherein the particle beam chamber is disposed between the ion extraction electrode and the shield.
